(19) United States
(12) Patent Application Publication
(10) Pub. No.: US 2007/0118779 A1
(43) Pub. Date: May 24, 2007

(54) Intelligent Test System and Related Method for Testing an Electronic Product

(76) Inventors: Yi-Chang Wu, Taipei Hsien (TW); Yi-Hsun Chen, Taipei Hsien (TW); Sen-Ta Chan, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 11/307,777

(22) Filed: Feb. 22, 2006

(30) Foreign Application Priority Data
Nov. 23, 2005 (TW) 094141204

(51) Int. Cl. G01R 31/28

(52) U.S. Cl. 714/725

(57) ABSTRACT

An intelligent test system includes a control device for generating control data, and a test device for testing an electronic product. The testing device includes a processor for transmitting a test signal to the electronic product according to the control data generated by the control device, and for controlling the intelligent test system according to the control data generated by the control device and feedback data generated by the electronic product in response to the test signal; and a memory for storing the feedback data generated by the electronic product. In doing so, the intelligent test system allows the electronic device test to execute smoothly without any interruption thereby reducing the time and cost of developing the electronic device.

### Background of the Invention

1. Field of the Invention

The present invention relates to an intelligent test system, and more particularly, to an intelligent test system and related method for testing an electronic product.

2. Description of the Prior Art

To ensure the stability of the normal functional operation and durability of an electronic device, the electronic device receives various types of tests according to each given situation as the product is being manufactured or before the product is shipped. A power on-and-off test is a good example. The power test is performed by repeatedly switching the electronic device on and off. This tests its durability when a user utilizes the electronic device over a long period of time. The test results help ensure that the electronic device functions normally after continued use. Numerous test apparatus have been developed to replace labor for performing automated electronic device tests. The replacement of human labor is attractive because the electronic device test otherwise requires huge time and labor resource consumption.

Please refer to FIG. 1. FIG. 1 illustrates a diagram of a conventional test apparatus 100. The conventional test apparatus 100 includes a control device 110 (such as a computer), and a signal converter 120. A test sequence of the control device 110 is setup by utilizing software to transmit a control signal to the signal converter 120. The signal converter 120 then converts the control signal transmitted from the control device 110 into a test signal (such as a switch signal) recognizable by the electronic device 130 to be transmitted to the electronic device 130. In this way the electronic device 130 can be tested.

Please refer to FIG. 2. FIG. 2 illustrates a diagram of another conventional test apparatus 200. The test apparatus 200 is a test box that operates independently and therefore differs from the test apparatus 100 in that way. A microprocessor 210 of the test apparatus 200 has preset test procedures, a user is only required to input the number of tests or other conditions on a user interface 220 of the test apparatus 200, the microprocessor 210 then generates a test signal, and the test signal is then outputted through an output end 222 to the electronic device 230, thus the electronic device 230 can be tested.

However, when a problem occurs in the test apparatus 100, 200 of the above-mentioned, the apparatus simply records only the number of the test failure and then the apparatus continues testing, or alternately can stop testing until a researcher is present to solve the problem. However, the test completion requires a long period of time and the testing process must be perform continuously. If the researcher is unable to immediately discover and solve the problem of the test failure, then test time is delayed resulting in an even longer test completion time period. The scenario described here can even affect the scheduled launching of an electronic device to the market. Also, the test apparatus 100, 200 of the above-mentioned is unable to record the situation of the test failure, thus researchers are not able to discover the cause of the test failure, hence this increases the difficulty of problem solving for the researchers. Even worse, as a result, the test may need to be restarted.

### SUMMARY OF THE INVENTION

The claimed invention discloses an intelligent test system for testing an electronic device. The intelligent test system comprises a control device for generating control data, and a test device for testing the electronic device. The test device comprises a processor for transmitting a test signal to the electronic device according to the control data generated by the control device, and for controlling the intelligent test system according to the control data generated by the control device and feedback data generated by the electronic product in response to the test signal; and a memory for storing the feedback data generated by the electronic device.

The claimed invention discloses a method of testing an electronic device by an intelligent test system. The method comprises editing a control data generated by a control device or a remote control device; transmitting a test signal generated by a test device to the electronic device according to an edited control data; executing the test to the electronic device after receiving the test signal generated by a test device; recording the feedback data while executing the test; and controlling the intelligent test system according to the control data generated by the control device and the feedback data generated by the electronic product in response to the test signal.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a diagram of a conventional test apparatus.

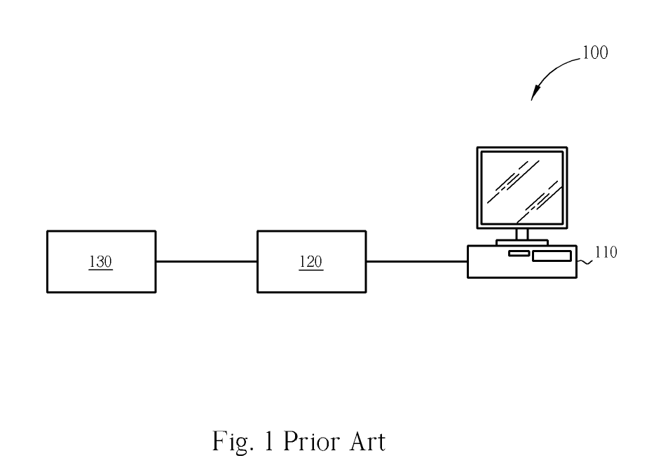

FIG. 2 illustrates a diagram of another conventional test apparatus.

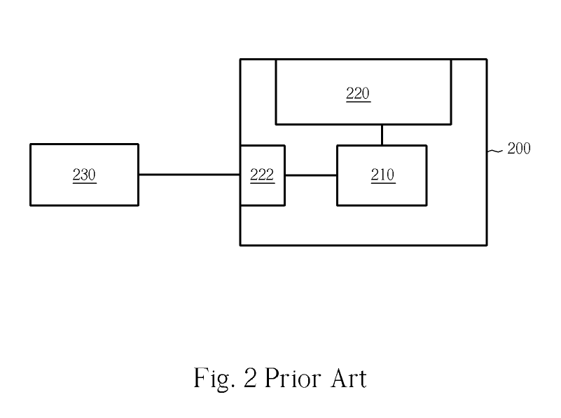

FIG. 3 illustrates a diagram of an intelligent test system according to the present invention.

FIG. 4 illustrates a flow chart according to the present invention.

### Detailed Description

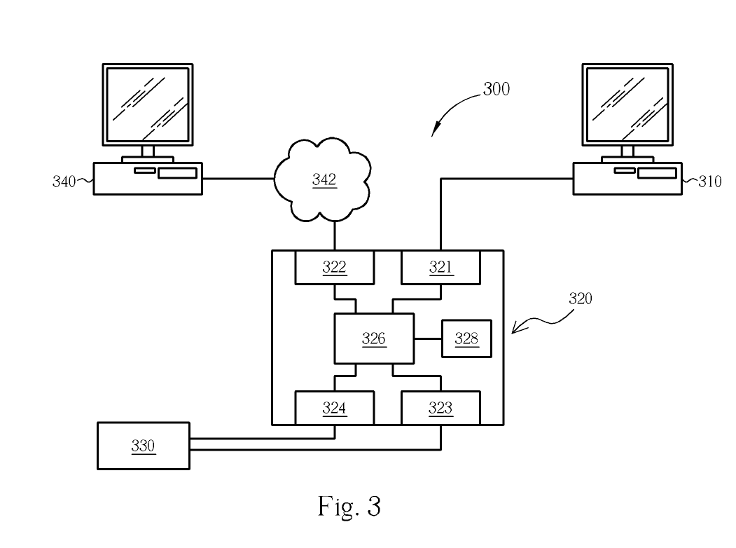

Please refer to FIG. 3. FIG. 3 illustrates a diagram of an intelligent test system 300 according to the present invention. The intelligent test system 300 includes a local control device 310, a remote control device 340, and a test device 320. The local control device 310 and the remote control device 340 can be a computer or other types of control interface. The test device 320 includes a local control end 321, a remote control end 322, a test end 323, a feedback end 324, a processor 326, and a memory 328. The local control end 321 is coupled to the local control device 310, the remote control end 322 is coupled to the remote control device 340 via a network 342. A researcher can generate control data through the local control device 310 or the remote control device 340 according to test procedures, and the control data is transmitted to the test device 320. The processor 326 is coupled among the local control end 321, the remote control end 322, the test end 323, the feedback end 324, and the memory 328. After the processor 326 receives the control data from the local control device 310 or the remote control device 340, the processor 326 will generate a test signal (such as a power on-and-off signal) recognizable by the electronic device 330 according to the control data transmitted from the local control device 310 or the remote control device 340. Next, the test signal is transmitted to the electronic device 330 through the test end 323. The electronic device 330 will execute the corresponding operation according to the received test signal; for example, a power-on self-test (POST) of a BIOS is executed to check whether each component of the electronic device 330 is functioning normally. The feedback end 324 is coupled to an output end of the electronic device 330, such as USB port or VGA port, therefore the electronic device 330 can generate the control data through the feedback end 324 when it is executing the POST, such as, providing as feedback, monitor image data or parameter data of each chip to the processor 326 (a preset program can be implanted into the electronic device 230 to output test data through designated input and output ends, and feedback data is transmitted back to the processor 326 through the feedback end 324). The processor 326 can analyze the feedback data to determine whether an error message has occurred.

If the test is successful, the processor 326 can store the feedback data or the test result into the memory 328 as reference for the researcher. If a problem is detected during the test, then the processor 326 can execute a corresponding operation according to the control data preset by the researcher. For example, when the processor 326 detects an error message in the received feedback data, the processor 326 determines whether the problem can be solved by the processor 326 itself according to the control data, if the problem can be solved by the processor 326, then the processor 326 will generate a debug signal according to the control data, and the debug signal is then transmitted to the electronic device 330 through the test end 323 to solve the problem, the processor 326 then stores the problem feedback data into the memory 328 as a reference for the researcher, and the test continues to prevent discontinuation which can effect the test schedule. If the processor 326 is unable to solve the problem itself, the processor 326 determines whether the test should be continued according to the control data, if the test should be continued, then the processor 326 stores the problem feedback data into the memory 328 and the test continues, if the test should be stopped, then the processor 326 will terminate the test and transmits a short text message, such as an email, to the local control device 310 or the remote control device 340, or can even transmit a short text message to a mobile phone to notify the researcher to solve the problem immediately. After the researcher acknowledges the problem, the researcher can control the test device 320 to solve the problem, in this way the problem can be solved quickly to prevent the test from falling behind schedule.

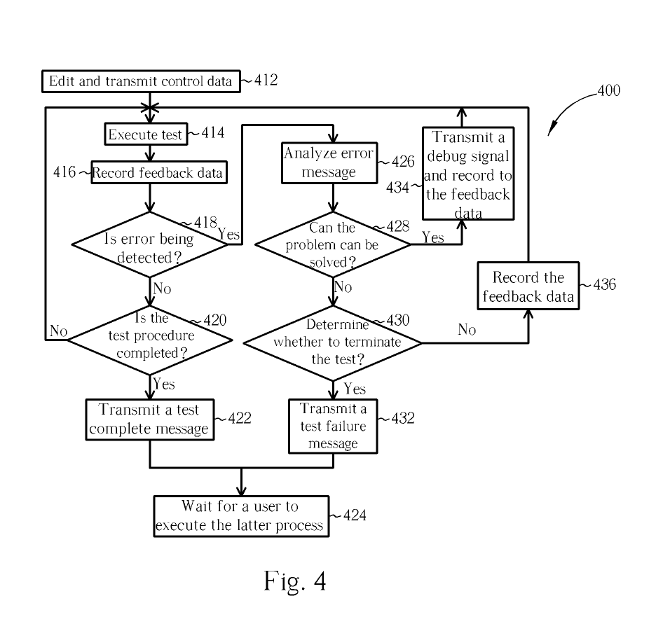

To explain the method of testing the electronic device 330 by the intelligent test system 300, FIG. 4 illustrates a flow chart 400 according to the present invention. Please refer to FIG. 4 and FIG. 3 at the same time. The flowchart 400 of FIG. 4 includes the following steps:

Step 412: a user transmits control data to the test device 320 through the local control device 310 or the remote control device 340;

Step 414: the test device 320 transmits the test signal to the electronic device 330 for executing the test;

Step 416: record the feedback data generated by the electronic device into the memory 328;

Step 418: is error being detected? If so execute step 420, if not execute step 422;

Step 420: is the test procedure completed? If not execute step 414, if so execute step 422;

Step 422: the test device 320 transmits a test complete message to the local control device 310 or the remote control device 340 to notify the user;

Step 424: wait for the user to execute the latter process through the local control device 310 or the remote control device 340;

Step 426: analyze the error message according to the control data;

Step 428: determine whether the problem can be solved? If not execute step 430, if so execute step 434;

Step 430: determine whether to terminate the test? If so execute step 432, if not execute step 436;

Step 432: the test device 320 transmits a test failure message to the local control device 310 or the remote control device 340 to notify the user, then execute step 424;

Step 434: the test device 320 transmits a debug signal to the electronic device 330 to solve the problem and records to the problem feedback data into the memory 328, and execute step 414; and

Step 436: the test device 320 records the problem feedback data into the memory 328, and execute step 414.

To achieve the above results, the steps of the flowchart 400 do not require a sequential execution. Because steps need not be adjacent to each other, other steps can be inserted thereby adding to and changing the execution sequence of the above-mentioned steps. Furthermore, the memory 328, other than storing test data, can also provide memory space for the processor 326 during operation, such as for storing the control data generated by the local control device 310 or the remote control device 340, therefore the test device 320 can operate independently after receiving the control data. The present invention can be realized by utilizing any of three components: a software, a firmware, a hardware, or any combination of said three components.

In comparison with the prior art, the intelligent test system 300 can detect a problem during a test and self-analyze the error message to determine whether the problem can be solved by the system itself or the test should be continued such that the problem test data will be recorded, hence a test interruption can be avoided and also the problem message can be provided to the researcher for further analysis and product modification. Also, when the intelligent test system 300 of the present invention cannot solve the problem by itself, the intelligent test system 300 can transmit a short text message to notify the researcher to process the problem quickly. In this way, regardless of when the test failure occurs, for example, on a public holiday, the researcher may still respond to solve the problem through the remote control device 340 so that the test can proceed. Therefore the intelligent test system 300 of the present invention allows the electronic device test to execute smoothly without any interruption thereby reducing the time and cost of developing the electronic device.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An intelligent test system for testing an electronic device, comprising:
a control device for generating control data; and
a test device, comprising:
a processor for transmitting a test signal to the electronic device according to the control data generated by the control device, and for controlling the intelligent test system according to the control data generated by the control device and feedback data generated by the electronic product in response to the test signal; and
a memory for storing the feedback data generated by the electronic device.

2. The intelligent test system of claim 1 wherein the control device is electronically coupled to the processor.

3. The intelligent test system of claim 1 wherein the control device is electronically coupled to the processor via a network.

4. The intelligent test system of claim 1 wherein the processor is electronically coupled to the memory.

5. The intelligent test system of claim 1 wherein the test device further comprises a test end coupled between the processor and the electronic device for outputting the test signal to the electronic device.

6. The intelligent test system of claim 1 wherein the test device further comprises a feedback end coupled between the processor and the electronic device for receiving the feedback data generated by the electronic device in response to the test signal.

7. The intelligent test system of claim 1 wherein the test device further comprises a control end coupled between the processor and the control device for receiving the control data generated by the control device.

8. A test device for testing the electronic device, comprising:
a control end for receiving control data generated by a control device;
a test end for outputting a test signal to the electronic device;
a feedback end for receiving a feedback data generated by the electronic device in response to the test signal;
a processor coupled among the control end, the test end, and the feedback end for generating the test signal according the control data generated by the control device, and for controlling the intelligent test system according to the control data generated by the control device and the feedback data generated by the electronic product in response to the test signal; and
a memory for storing the feedback data generated by the electronic device.

9. The test device of claim 8 wherein the control end is electronically coupled to the local control device.

10. The test of claim 8 wherein the control end is electronically coupled to the remote control device via the network.

11. The test device of claim 8 wherein the test end is electronically coupled to the electronic device.

12. The test device of claim 8 wherein the feedback end is electronically coupled to the electronic device.

13. The test device of claim 8 wherein the processor is coupled to the memory.

14. A method of testing an electronic device by an intelligent test system, comprising:
editing a control data generated by a control device or a remote control device;
transmitting a test signal generated by a test device to the electronic device according to an edited control data;
executing the test to the electronic device after receiving the test signal generated by a test device;
recording the feedback data while executing the test; and
controlling the intelligent test system according to the control data generated by the control device and the feedback data generated by the electronic product in response to the test signal.

15. The method of claim 14 wherein controlling the intelligent test system comprises analyzing the feedback data generated by the electronic device into a memory.

16. The method of claim 14 wherein controlling the intelligent test system comprises transmitting a short text message.

17. The method of claim 14 wherein controlling the intelligent test system comprises transmitting a debug signal to the electronic device.
